(19) United States
(12) Patent Application Publication
(10) Pub. No.: US 2025/0022742 A1
(43) Pub. Date: Jan. 16, 2025

(54) TEMPORARY FIXATION SUBSTRATE, METHOD OF MANUFACTURING TEMPORARY FIXATION SUBSTRATE, AND METHOD OF TEMPORARY FIXATION

(71) Applicant: NGK INSULATORS, LTD., Nagoya-shi (JP)

(72) Inventors: Yoshio KIKUCHI, Nagoya-shi (JP); Sugio MIYAZAWA, Kasugai-shi (JP); Masaru NOMURA, Owariasahi-shi (JP); Daisuke YABU, Komaki-shi (JP)

(21) Appl. No.: 18/895,769

(22) Filed: Sep. 25, 2024

Related U.S. Application Data
(63) Continuation of application No. PCT/JP2023/007832, filed on Mar. 2, 2023.

(30) Foreign Application Priority Data
Mar. 31, 2022 (JP) 2022-059157

(51) Int. Cl. H01L 21/683; H01L 21/56

(52) U.S. Cl. CPC H01L 21/6836; H01L 21/565; H01L 21/568

(57) ABSTRACT

A temporary fixation substrate having one main surface to which a plurality of electronic components adhere and are temporarily fixed by a resin mold has a chamfered region at an end over an entire circumference of each of the one main surface and the other main surface, and an arithmetic average roughness of the chamfered region at least on a side of the one main surface is 0.1 μm to 10 μm and is greater than an arithmetic average roughness of the one main surface.

### CROSS-REFERENCE TO RELATED APPLICATION

This application is a continuation application of PCT/JP2023/007832, filed on Mar. 2, 2023, which claims the benefit of priority of Japanese Patent Application No. 2022-059157, filed on Mar. 31, 2022, the entire contents of which are incorporated herein by reference.

### BACKGROUND OF THE INVENTION

### Field of the Invention

The present invention relates to a temporary fixation substrate for use in a process for manufacturing a semiconductor package.

### Description of the Background Art

Fan-out wafer level packaging (FOWLP) technology is known as technology for manufacturing a semiconductor package. The FOWLP technology generally includes a step of performing resin molding on a temporary fixation substrate to which semiconductor chips have temporarily been fixed with an adhesive, a step of grinding a resin mold to expose electrode ends of the semiconductor chips, a step of forming a thin-film redistribution layer (multilayer wiring) and a solder ball on a surface from which the electrode ends are exposed, and a step of singulating each package and peeling the package from the temporary fixation substrate to obtain a semiconductor package having a lower profile.

Use of a translucent ceramic substrate as a temporary fixation substrate for chips in the FOWLP technology has already been known (see Japanese Patent No. 6430081 and Japanese Patent No. 6420023, for example). The translucent ceramic substrate meets all the requirements for the temporary fixation substrate, including high flatness required to expose electrode ends, high stiffness and a reverse warping shape required to suppress warpage during formation of multilayer wiring, translucency allowing transmission of laser light for curing of an adhesive, and chemical resistance for cleaning after use for reuse.

A conventional temporary fixation substrate, however, has a problem in that a peeling failure, that is, peeling of a resin portion at a circumference occurs to reduce a yield.

The conventional temporary fixation substrate also has a problem in that chipping (cracking) occurs at the circumference to reduce the yield.

### SUMMARY

The present invention relates to a temporary fixation substrate for use in a process for manufacturing a semiconductor package.

According to the present invention, a temporary fixation substrate includes: one main surface to which a predetermined fixed object is temporarily fixed; the other main surface; and a chamfered region at an end over an entire circumference of each of the one main surface and the other main surface. An arithmetic average roughness of the chamfered region at least on a side of the one main surface is 0.1 μm to 10 μm and is greater than an arithmetic average roughness of the one main surface.

According to the invention, during a process of temporarily fixing the fixed object, such as electronic components, to the temporary fixation substrate, peeling of the fixed object, an adhesive layer or an adhering layer, and other resins from the temporary fixation substrate can suitably be suppressed.

It is thus an object of the present invention to provide a temporary fixation substrate enabling suppression of a peeling failure and obtainment of a semiconductor package with a higher yield.

Preferably, an arithmetic average roughness of a lateral end of the temporary fixation substrate is smaller than the arithmetic average roughness of the chamfered region, greater than the arithmetic average roughness of the one main surface, and 5 μm or less.

In this case, chipping at the lateral end of the temporary fixation substrate can suitably be suppressed.

It is thus also an object of the present invention to suppress chipping at a circumference of the temporary fixation substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of one main surface (a front surface) 1a of a temporary fixation substrate 1 according to a first embodiment.

FIG. 2 is an enlarged cross-sectional view near a lateral end 1e of the temporary fixation substrate 1 illustrating a chamfered region 2.

FIGS. 3A, 3B, and 3C are schematic cross-sectional views illustrating steps during a process for preparing a semiconductor package with FOWLP technology using the temporary fixation substrate 1.

FIG. 4 is a flowchart generally showing a process for manufacturing the temporary fixation substrate 1.

FIG. 5 is a diagram schematically showing chamfering of the temporary fixation substrate 1 using a chamfering apparatus 100.

FIG. 6 is an enlarged schematic view of a portion A of FIG. 5 illustrating chamfering.

FIG. 7 is a schematic cross-sectional view illustrating a portion of a lapping apparatus 200 that laps the temporary fixation substrate 1.

FIG. 8 is a perspective view of a portion of the lapping apparatus 200 without an upper surface plate 202.

FIG. 9 is a diagram schematically showing polishing of the lateral end 1e of the temporary fixation substrate 1 not having the chamfered region 2 using the lapping apparatus 200.

### DESCRIPTION OF THE PREFERRED EMBODIMENTS

### First Embodiment

### <Temporary Fixation Substrate>

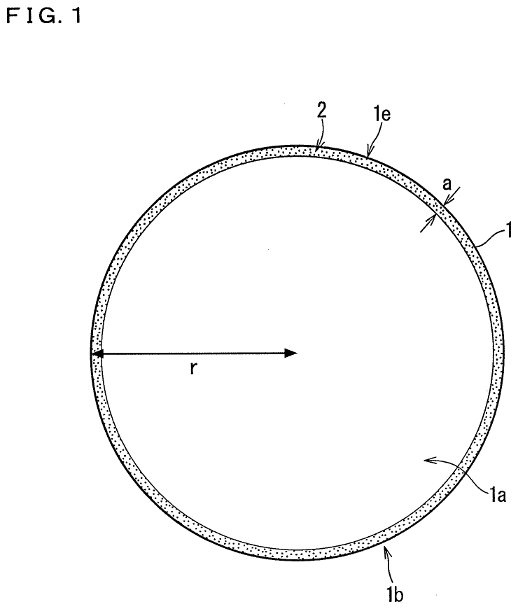

FIG. 1 is a plan view of one main surface (a front surface) 1a of a temporary fixation substrate 1 according to a first embodiment of the present invention. The temporary fixation substrate 1 is a substrate to which semiconductor chips are temporarily fixed in preparing a semiconductor package with fan-out wafer level packaging (FOWLP) technology.

The temporary fixation substrate 1 is a translucent ceramic substrate having a diameter of several hundred millimeters (e.g., 300 mm), a thickness of several hundred micrometers to several millimeters (e.g., 1 mm), an in-plane thickness difference of several micrometers or less (e.g., 3 μm or less), and a warpage amount of several hundred micrometers or less (e.g., 200 μm). Assume that translucent ceramics are ceramics having a forward total light transmittance of 20% or more in a full wavelength range of 200 nm to 1500 nm in the present embodiment. Examples of such translucent ceramics include alumina, silicon nitride, aluminum nitride, and silicon oxide. One suitable example of the temporary fixation substrate 1 mainly comprises alumina and has a forward total light transmittance of 70% or more at a wavelength of 1500 nm, for example. When the temporary fixation substrate 1 is based on alumina, alumina powder having a high purity of 99.9% or more (preferably 99.95% or more) is preferably used as a raw material, and magnesium oxide and zirconia (ZrO₂) or yttria (Y₂O₃) as a sintering agent are preferably added to the alumina powder.

The front surface 1a as a surface over which the semiconductor chips are arranged as well as the other main surface (a rear surface) 1b are polished in advance to be flat polished surfaces each having a small surface roughness. More particularly, the front surface 1a and the rear surface 1b each have the above-mentioned in-plane thickness difference of several micrometers or less and an arithmetic average roughness Ra of 100 nm or less (preferably 20 nm or less). More specifically, the front surface 1a and the rear surface 1b are lapped surfaces. While there is no particular limitation on a lower limit of the arithmetic average roughness Ra of each of the front surface 1a and the rear surface 1b, an arithmetic average roughness Ra of 1 nm will suffice for practical use.

The temporary fixation substrate 1 according to the present embodiment, however, has a chamfered region 2 at an end over an entire circumference of the front surface 1a. Although not illustrated, the chamfered region 2 is similarly provided to the rear surface 1b. The above-mentioned arithmetic average roughness Ra of each of the front surface 1a and the rear surface 1b of 100 nm or less is thus strictly achieved in a region excluding the chamfered region 2. A portion of the front surface 1a excluding the chamfered region 2 and a portion of the rear surface 1b excluding the chamfered region 2 are hereinafter also respectively referred to as a flat front surface 1a and a flat rear surface 1b.

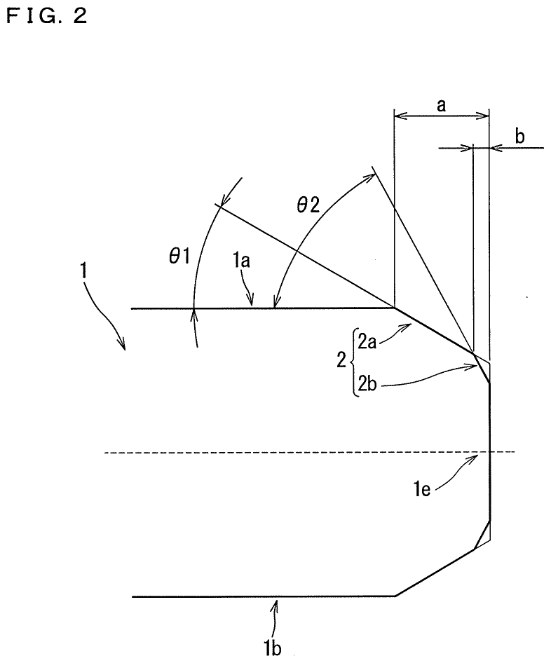

FIG. 2 is an enlarged cross-sectional view near a lateral end 1e of the temporary fixation substrate 1 illustrating the chamfered region 2.

FIG. 2 illustrates a case where the chamfered region 2 has a two-step configuration including a first chamfer 2a inclined relative to the flat front surface 1a at an angle of inclination θ1 and a second chamfer 2b inclined relative to the flat front surface 1a at an angle of inclination θ2 (>θ1). The second chamfer 2b is provided in a range of a predetermined width b (<a) from the lateral end 1e. The chamfered region 2 having the two-step configuration including the first chamfer 2a and the second chamfer 2b is similarly provided on a side of the flat rear surface 1b. The chamfered region 2 may have a single-step configuration only including the first chamfer 2a without the second chamfer 2b.

The angle of inclination θ1 is preferably 5° to 55° (e.g., 30°). The angle of inclination θ2 when the chamfered region 2 has the two-step configuration is preferably 35° to 85° (e.g., 60°). An inequality θ1<θ2 holds true.

The temporary fixation substrate 1 has the chamfered region 2 satisfying a range of an angle of inclination as described above to suitably suppress chipping. That is to say, while chipping of a corner where the front surface 1a and the rear surface 1b are each perpendicular to the lateral end 1e is likely to occur in the temporary fixation substrate 1 not having the chamfered region 2, chipping is extremely less likely to occur in the temporary fixation substrate 1 according to the present embodiment because the temporary fixation substrate 1 having the chamfered region 2 does not have such a perpendicular corner, and an angle formed by the chamfered region 2 and each of the front surface 1a and the rear surface 1b and an angle formed by the chamfered region 2 and the lateral end 1e are obtuse angles.

That is to say, the chamfered region 2 has an effect of suppressing a failure due to chipping and increasing a manufacturing yield of the temporary fixation substrate 1. In particular, the chamfered region 2 having the two-step configuration including the first chamfer 2a and the second chamfer 2b is more effective in suppressing chipping because above described obtuse angles are provided in two steps.

### <Process for Preparing Semiconductor Package and Effect of Roughening of Chamfer>

From among the chamfered regions 2 provided to the temporary fixation substrate 1 as described above, the chamfered region 2 provided at least on a side of the front surface (one main surface) 1a has a rough surface having a greater surface roughness than the flat front surface 1a. Specifically, the chamfered region 2 has an arithmetic average roughness Ra of 0.1 μm to 10 μm. This is intended to secure the manufacturing yield of the semiconductor package. This will be described below.

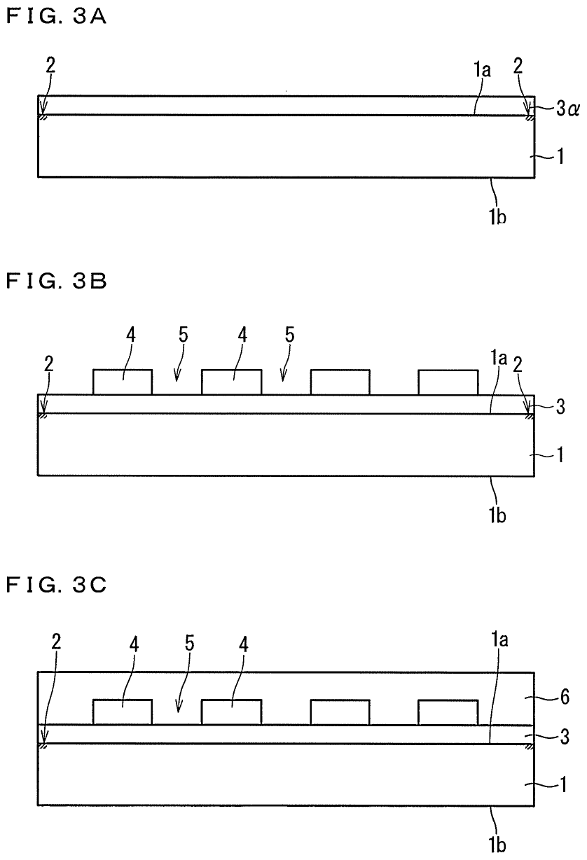

FIGS. 3A to 3C are schematic cross-sectional views illustrating steps during a process for preparing the semiconductor package with the FOWLP technology using the temporary fixation substrate 1. The chamfered region 2 is hatched only on a side of the front surface 1a in each of FIGS. 3A to 3C for ease of illustration.

In the process for preparing the semiconductor package, a layer formed of an adhesive (an adhesive layer) 3a is first formed on the temporary fixation substrate 1 as illustrated in FIG. 3A. Examples of the adhesive include double-sided tape and a hot melt-based adhesive, and various known schemes, such as roll coating, spray coating, screen printing, and spin coating, are applicable to formation of the adhesive.

Next, as illustrated in FIG. 3B, a plurality of (many) semiconductor chips 4 are arranged on the adhesive layer 3a. The semiconductor chips 4 are arranged in a region inward of the chamfered region 2. The adhesive layer 3a is then cured into an adhering layer 3. A curing scheme is selected from heating, ultraviolet irradiation, and the like according to a material for the adhesive used for the adhesive layer 3a and the like. The semiconductor chips 4 are thereby adhesively fixed to the temporary fixation substrate 1.

When the semiconductor chips 4 are fixed to the temporary fixation substrate 1 as described above, a molding resin is cast onto an entire upper surface of the temporary fixation substrate 1, that is, onto gaps 5 between the semiconductor chips 4 and entire upper surfaces of the semiconductor chips 4. The molding resin is cured into a resin mold 6 as illustrated in FIG. 3C. Examples of the molding resin include an epoxy-based resin, a polyimide-based resin, a polyurethane-based resin, and a urethane-based resin.

The resin mold 6 is ground until electrode ends of the semiconductor chips 4 are exposed, and then a redistribution layer and a solder ball are formed on the ground surface. Each package is finally singulated and separated from the temporary fixation substrate 1 by laser lift-off.

The chamfered region 2 at the circumference of the temporary fixation substrate 1 produces an effect (peeling suppression effect) of suppressing a failure (peeling failure) of peeling of resins (the adhering layer 3 and the resin mold 6) from the temporary fixation substrate 1 until singulation and laser lift-off in the process for preparing the semiconductor package as described above.

In a case of a conventional temporary fixation substrate, the resins may be peeled from the temporary fixation substrate because air enters between the temporary fixation substrate and the resins from outside near the circumference of the temporary fixation substrate during the above-mentioned process for preparing the semiconductor package to form bubbles.

When the temporary fixation substrate 1 according to the present embodiment is used, however, the adhesive and further the molding resin enter into the chamfered region 2 provided at the circumference of the front surface 1a, which is a rough surface having a sufficiently greater surface roughness than the front surface 1a, thereby to produce an anchoring effect between the temporary fixation substrate 1 and the resins in the chamfered region 2. The anchoring effect suppresses formation of bubbles and further peeling of the resins at the circumference of the temporary fixation substrate 1. The presence or absence of bubbles can be identified by visual inspection or observation with a stereo microscope of the temporary fixation substrate 1 from a side of the rear surface 1b. It is regarded that the resins are peeled not only when a portion where the resins and the temporary fixation substrate 1 are separated is identified as a result of visual inspection of the temporary fixation substrate 1 from a side of the lateral end 1e but also when bubbles having a size in a longitudinal or transverse direction of 3 mm or more are identified as a result of visual inspection or observation with the stereo microscope from a side of the rear surface 1b in the present embodiment.

When the temporary fixation substrate 1 has the chamfered region 2 having an arithmetic average roughness Ra of 0.1 μm to 10 m, a rate of a peeling failure (peeling failure rate) counted in units of substrates is suppressed to 3% or less. The chamfered region 2 preferably has an arithmetic average roughness Ra of 0.5 μm to 2 km.

In terms of suppression of peeling, a width a of the chamfered region 2 is only required to be up to 1% of a radius r of the temporary fixation substrate 1, and the chamfered region 2 is not required to be provided further inwards beyond the width. In a case of the temporary fixation substrate 1 having a diameter of 300 mm (r=150 mm), for example, the width a is preferably approximately 0.2 mm to 0.5 mm. The width b of the second chamfer 2b is preferably approximately 0.01 mm to 0.11 mm. The presence of the chamfered region 2 does not interfere with laser lift-off.

### <Process for Manufacturing Temporary Fixation Substrate>

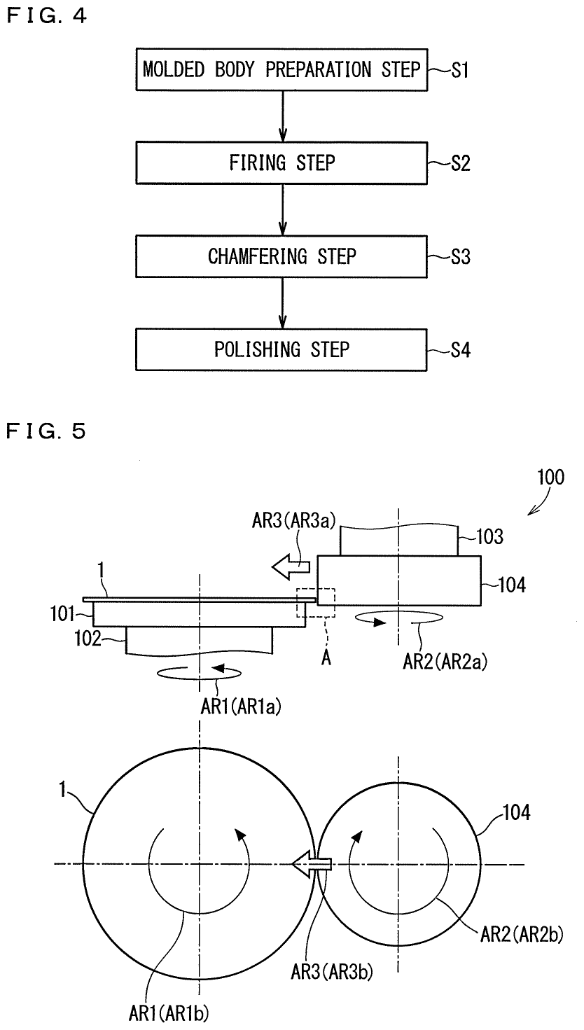

A process for manufacturing the temporary fixation substrate 1 having the chamfered region 2 will be described next. FIG. 4 is a flowchart generally showing the process for manufacturing the temporary fixation substrate 1. The temporary fixation substrate 1 is generally manufactured through a molded body preparation step (step S1), a firing step (step S2), a chamfering step (step S3), and a polishing step (step S4).

In manufacturing the temporary fixation substrate 1, a molded body mainly including translucent ceramic powder is first prepared (step S1). For example, the above-mentioned translucent ceramic raw powder of alumina and the like, ceramic powder such as magnesium oxide and a sintering agent, and an organic material such as a binder and a solvent are mixed in a ball mill and the like to manufacture a slurry, and the slurry is molded into tape. A plurality of rectangular sheets each having a predetermined size obtained by shearing (cutting) the obtained tape are laminated and pressed, and the pressed laminate is die cut into a circular shape. A disc-shaped molded body is thereby obtained. Alternatively, the molded body may be obtained by doctor blading, extrusion, gel casting, and the like.

Next, the molded body thus formed is fired (step S2). An organic component is thereby desorbed to obtain a sintered body of ceramics (the temporary fixation substrate 1 before chamfering and polishing).

Firing is preferably performed by performing temporary firing in an atmospheric furnace and then performing main firing in a hydrogen furnace. A sintering temperature during main firing is preferably 1700° C. to 1900° C. and is more preferably 1750° C. to 1850° C. in terms of densification of the sintered body.

After main firing, the obtained sintered body may further be annealed in the hydrogen furnace for the purpose of adjusting (correcting) warpage. Annealing is preferably performed at a temperature within ±100° C. with respect to a maximum temperature in main firing and is more preferably performed at 1900° C. or less in terms of facilitating discharge of the sintering agent while preventing deformation and growth of abnormal particles. Annealing is preferably performed for one to six hours.

When the sintered body (the temporary fixation substrate 1 before chamfering and polishing) is obtained, an entire circumference of each of a front surface and a rear surface (opposite main surfaces) of the sintered body is chamfered next (step S3). The temporary fixation substrate 1 before chamfering and the temporary fixation substrate 1 before polishing are each simply referred to as the temporary fixation substrate 1 in description made below for the sake of convenience.

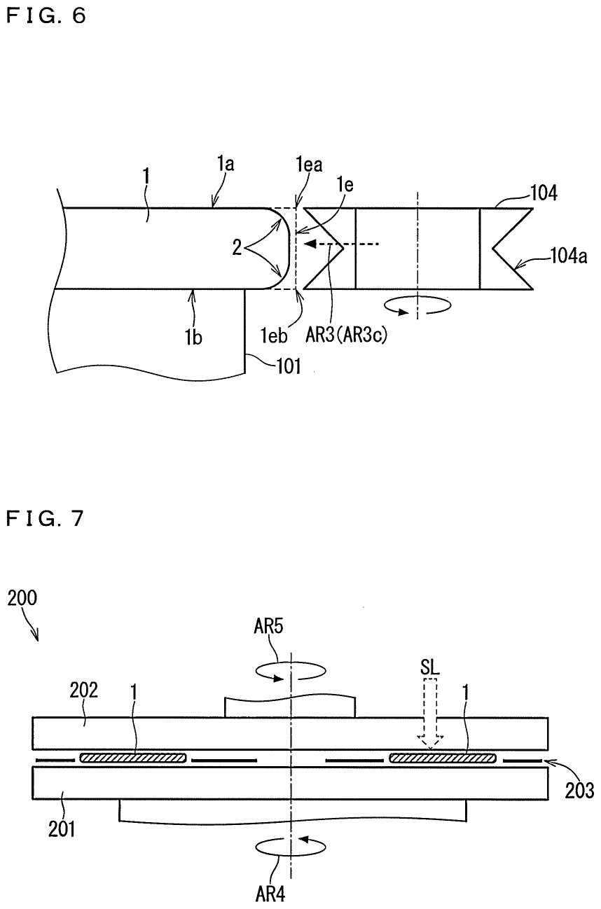

FIG. 5 is a diagram schematically showing chamfering of the temporary fixation substrate 1 using a chamfering apparatus (beveling machine) 100. The chamfering apparatus 100 includes a table 101, a table rotation mechanism 102, a whetstone holding moving mechanism 103, and a whetstone 104. FIG. 6 is an enlarged schematic view of a portion A of FIG. 5 illustrating chamfering.

The temporary fixation substrate 1 to be chamfered can horizontally be mounted on an upper surface of the table 101, and the table 101 can be rotated in a horizontal plane together with the mounted temporary fixation substrate 1 by operation of the table rotation mechanism 102.

The whetstone holding moving mechanism 103 can hold the disc-shaped whetstone 104 in a horizontal posture at a lower end thereof and can perform rotation operation and forward and rearward movement operation in a horizontal plane while holding the whetstone 104.

The whetstone 104 is disc-shaped, and a circumferential end thereof is a blade 104a that is isosceles triangle-shaped in cross section as illustrated in FIG. 6. A count of the whetstone 104 (blade 104a) is selected so that the chamfered region 2 as eventually formed has an arithmetic average roughness Ra in the above-mentioned range of 0.1 m to 10 m.

In chamfering, the temporary fixation substrate 1 is first mounted on the upper surface of the table 101. On the other hand, the whetstone 104 is attached to the whetstone holding moving mechanism 103. In this case, the temporary fixation substrate 1 and the whetstone 104 are aligned so that a center height (a location in a vertical direction) in a thickness direction of the temporary fixation substrate 1 and a center height in a thickness direction of the whetstone 104 coincide with each other.

With the table 101 on which the temporary fixation substrate 1 is mounted being horizontally rotated by the table rotation mechanism 102 as indicated by arrows AR1 (AR1a and AR1b), the whetstone holding moving mechanism 103 translates the whetstone 104 toward the lateral end 1e of the temporary fixation substrate 1 as indicated by arrows AR3 (AR3a and AR3b) while horizontally rotating the whetstone 104 in a direction opposite the table 101 as indicated by arrows AR2 (AR2a and AR2b).

With rotation and translation, the blade 104a of the whetstone 104 approaches the lateral end 1e of the temporary fixation substrate 1 and eventually comes into contact with two upper and lower edges 1ea and 1eb of the side end 1e of the temporary fixation substrate 1. Rotation and translation of the whetstone 104 are continued after contact, so that the lateral end 1e of the temporary fixation substrate 1 is gradually shaved from the edges 1ea and 1eb to eventually form the chamfered regions 2.

When the chamfered region 2 has the two-step configuration, two types of whetstones 104 having different angles of the blade 104a are sequentially used. Alternatively, a single whetstone 104 may have a plurality of blades 104a having different angles, and the blades 104a may sequentially be used to achieve the two-step configuration of the chamfered region 2.

The semiconductor chips 4 are generally not mounted on the rear surface 1b of the temporary fixation substrate 1 in the above-mentioned process, so that the chamfered region 2 formed on a side of the rear surface 1b is not necessarily required to be roughened in terms of suppression of peeling of the resins, but there is no particular problem even when the chamfered region 2 on a side of the rear surface 1b is roughened together with that on a side of the front surface 1a in chamfering using the chamfering apparatus 100. It can rather be said that it is preferable to similarly perform chamfering on a side of the front surface 1a and on a side of the rear surface 1b using the blade 104a having the same count in terms of symmetry of the shape of the lateral end 1e.

The front surface and the rear surface (opposite main surfaces) of the temporary fixation substrate 1 after chamfering are finally polished (step S4).

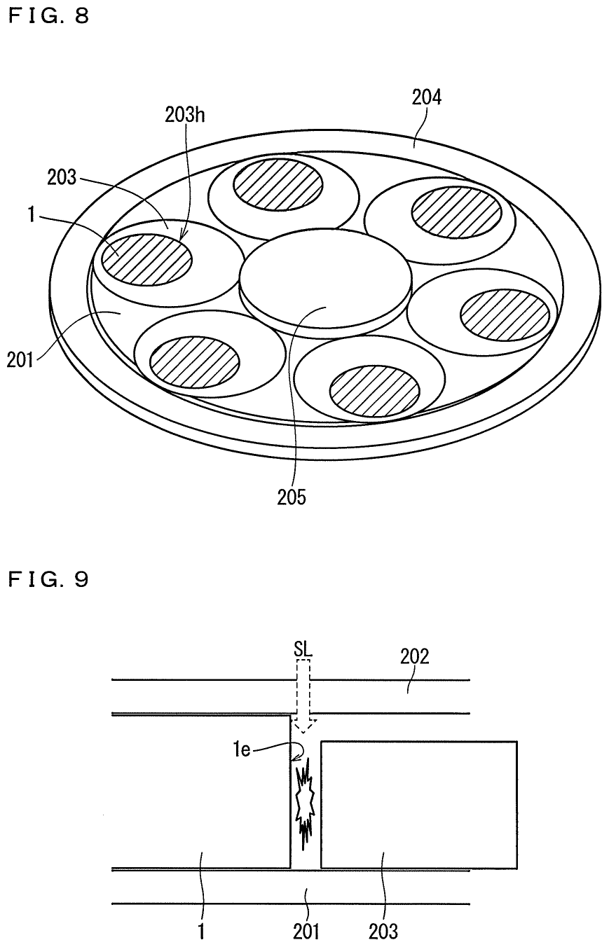

FIG. 7 is a schematic cross-sectional view illustrating a portion of a lapping apparatus 200 that laps the temporary fixation substrate 1. The lapping apparatus 200 includes a lower surface plate 201, an upper surface plate 202, and a plurality of carriers 203. FIG. 8 is a perspective view of a portion of the lapping apparatus 200, in which the upper surface plate 202 is not illustrated.

The lower surface plate 201 and the upper surface plate 202 can be rotated in a horizontal plane coaxially and in opposite directions as indicated by arrows AR4 and AR5. Examples of a material for the lower surface plate 201 and the upper surface plate 202 include copper, resin copper, and tin. Alternatively, a polishing pad may be attached to a metal surface plate and used. In this case, examples of the polishing pad include a hard urethane pad, a nonwoven pad, and a suede pad.

Each of the carriers 203 has a circular through hole 203h into which the temporary fixation substrate 1 to be polished is fitted and, with rotation of the lower surface plate 201 and the upper surface plate 202, can rotate and revolve between an annular guide 204 and a central shaft 205.

In the lapping apparatus 200, with the plurality of carriers 203 into each of which the temporary fixation substrate 1 to be polished is fitted generally being sandwiched between the lower surface plate 201 and the upper surface plate 202, the lower surface plate 201 and the upper surface plate 202 are rotated in opposite directions as indicated by the arrows AR4 and AR5 while a slurry SL is dripped between the lower surface plate 201 and the upper surface plate 202. The opposite main surfaces of the temporary fixation substrate 1 are thereby simultaneously polished, so that the flat front surface 1a and the flat rear surface 1b each having an arithmetic average roughness Ra of 100 nm or less (preferably 20 nm or less) can be obtained. An example of the slurry SL includes a water-based or an oil-based diamond slurry.

While the chamfered region 2 is polished to some extent by lapping, the surface roughness of the chamfered region 2 having been roughened in advance is largely unchanged from that before polishing.

The temporary fixation substrate 1 according to the present embodiment having the chamfered region 2 is obtained through the above-mentioned steps.

As described above, according to the present embodiment, the chamfered region is provided over the entire circumference of each of the opposite main surfaces of the temporary fixation substrate used to temporarily fix the semiconductor chips in the process for preparing the semiconductor package with the FOWLP technology to suitably suppress chipping of each of the corners of the temporary fixation substrate. In addition, the chamfered region provided at the circumference of the main surface to which the semiconductor chips are temporarily fixed is caused to have the rough surface having a greater surface roughness than the main surface, so that peeling of the resins from the temporary fixation substrate during the above-mentioned process can suitably be suppressed.

### Second Embodiment

In the above-mentioned first embodiment, the chamfered region 2 having the rough surface is formed using the chamfering apparatus 100, and then each of the opposite surfaces of the temporary fixation substrate 1 is lapped using the lapping apparatus 200 to form the flat front surface 1a to which the semiconductor chips 4 are temporarily fixed.

In a lapping step performed by the lapping apparatus 200, the lateral end 1e is polished to some extent by the nature of the scheme. That is to say, the surface roughness of the lateral end 1e is reduced by lapping. Thus, in addition to the flat front surface 1a and the flat rear surface 1b, the lateral end 1e has a smaller surface roughness (arithmetic average roughness Ra) than the chamfered region 2. Reduction in surface roughness of the lateral end 1e due to lapping as described above has an effect of suppressing in-plane chipping of the lateral end 1e. Furthermore, the effect can be obtained not only in the temporary fixation substrate 1 having the chamfered region 2 but also in the temporary fixation substrate 1 manufactured without the chamfering step.

FIG. 9 is a diagram schematically showing polishing of the lateral end 1e of a temporary fixation substrate 1 not having the chamfered region 2 using the lapping apparatus 200.

As described above, while the slurry SL is dripped between the lower surface plate 201 and the upper surface plate 202 sandwiching the carrier 203 and the temporary fixation substrate 1 in the lapping apparatus, the slurry SL also enters between the lateral end 1e of the temporary fixation substrate 1 and the carrier 203 as illustrated in FIG. 9. The lateral end 1e of the temporary fixation substrate 1 is polished by the entering slurry SL. The same applies to a case where the temporary fixation substrate 1 has the chamfered region 2.

When the lateral end 1e has an arithmetic average roughness Ra of 5 μm or less, a rate of chipping (chipping failure rate) counted in units of substrates is suppressed to less than 3.0%. When the lateral end 1e has an arithmetic average roughness Ra of 2 μm or less, the chipping failure rate is suppressed to 1.0% or less.

Furthermore, in a case of the temporary fixation substrate 1 having the chamfered region 2 as in the first embodiment, when the lateral end 1e has an arithmetic average roughness Ra of 2 μm or less, the chipping failure rate is suppressed to 0.5% or less.

While there is no particular limitation on a lower limit of the arithmetic average roughness Ra of the lateral end 1e, an arithmetic average roughness Ra of 0.01 μm or more will suffice for practical use. A main target of lapping, however, is the main surface of the temporary fixation substrate 1, so that progression of polishing of the lateral end 1e is slower than that of the main surface. The arithmetic average roughness Ra of the lateral end 1e thus generally has a greater value than the arithmetic average roughness Ra of the flat front surface 1a and the arithmetic average roughness Ra of the flat rear surface 1b.

As described above, chipping of the lateral end of the temporary fixation substrate used to temporarily fix the semiconductor chips in the process for preparing the semiconductor package with the FOWLP technology can suitably be suppressed by setting the arithmetic average roughness Ra of the lateral end to 5 μm or less.

### (Modifications)

While the temporary fixation substrate having the chamfered region is used as the substrate to which the plurality of semiconductor chips are temporarily fixed in preparing the semiconductor package with the FOWLP technology in the above-mentioned embodiments, a use aspect of the temporary fixation substrate is not limited to this aspect, and the temporary fixation substrate may be used to temporarily fix an electronic component other than the semiconductor chips. That is to say, the temporary fixation substrate according to the above-mentioned embodiments may be used for the purpose of suppressing peeling of the resins from the temporary fixation substrate when the resin mold is formed after a plurality of any electronic components adhere to the temporary fixation substrate with an adhesive.

Alternatively, after various semiconductor substrates are temporarily fixed to the temporary fixation substrate having the chamfered region with the adhesive, and the temporarily fixed semiconductor substrates are subjected to desired treatment, the temporary fixation substrate may be peeled similarly to that in the above-mentioned embodiments. Examples of the semiconductor substrates include various semiconductor substrates including a silicon substrate and a compound semiconductor substrate or an epitaxial substrate and other composite substrates, double-layer substrates, multi-layer substrates, and the like including the silicon substrate and the compound semiconductor substrate as underlying substrates. An effect similar to the effect obtained in the above-mentioned embodiments can be obtained also in this case.

### Examples

### (Confirmation of Effect of Roughening of Chamfered Region)

For each of five types of temporary fixation substrates 1 having different combinations of the arithmetic average roughness Ra of the flat front surface 1a and the arithmetic average roughness Ra of the chamfered region 2 (Conditions 1 to 5), 200 temporary fixation substrates 1 were prepared. The chamfered region 2 had the two-step configuration, and the angles of inclination θ1 and θ2 were respectively 300 and 60°. Each of the temporary fixation substrates 1 was subjected to treatment to temporary fixation of the semiconductor chips 4 using the resin mold 6 along the process illustrated in FIGS. 3A to 3C.

Temporary fixation substrates were prepared similarly to those under Conditions 1, 4, and 5 except that the chamfered region 2 was not formed (Condition 6).

For each of all the obtained samples (a laminate of the temporary fixation substrate 1, the semiconductor chips 4, and the resin), whether peeling of the resin from the temporary fixation substrate 1 occurred was determined by visual inspection, and the peeling failure rate in each of Examples was obtained. Specifically, the temporary fixation substrate 1 was visually inspected from a side of the lateral end 1e and a side of the rear surface 1b, and it was determined that peeling occurred, in the case that the resin mold 6 and the temporary fixation substrate 1 were separated at the lateral end 1e or the case that a bubble having a minimum size of 3 mm or more was present in at least one of a radial direction or a circumferential direction of the temporary fixation substrate 1 in observation from a side of the rear surface 1b.

Table 1 shows a list of a value of the arithmetic average roughness Ra of the flat front surface 1a, a value of the arithmetic average roughness Ra of the chamfered region 2, and an evaluation result of the peeling failure rate for each of Examples and Comparative Example.

TABLE 1

| | FRONT | CHAMFERED | PEELING |
|---|---|---|---|
| ROUGHNESS | SURFACE | REGION | FAILURE |
| Ra | (nm) | (μm) | RATE |
| CONDITION 1 | 20 | 0.2 | ◯ |
| CONDITION 2 | 17 | 4.5 | ◯ |
| CONDITION 3 | 35 | 9.5 | ◯ |
| CONDITION 4 | 20 | 1.5 | ◯ |
| CONDITION 5 | 20 | 0.8 | ◯ |
| CONDITION 6 | 20 | W/O CHAMFERED | X |
| | | REGION | |

As for evaluation of the peeling failure rate, it was determined that peeling of the resin was successfully suppressed for each of the temporary fixation substrates 1 prepared under conditions that a value of the peeling failure rate remained at 3% or less. Specifically, Conditions 1 to 5 corresponded to these conditions. In Table 1, a “PEELING FAILURE RATE” column for each of Conditions 1 to 5 is marked with a circle.

On the other hand, it was determined that peeling of the resin was not sufficiently suppressed for each of the temporary fixation substrates 1 prepared under a condition that a value of the peeling failure rate reached more than 3%. Specifically, only Condition 6 corresponded to this condition. Specifically, the peeling failure rate under Condition 6 was 4.5%. In Table 1, the “PEELING FAILURE RATE” column for Condition 6 is marked with a cross.

The above-mentioned results show that the chamfered region 2 having an arithmetic average roughness Ra in a range of 0.1 μm to 10 m, which is a sufficiently rougher surface than the front surface 1a, has an effect of suppressing peeling of the resin from the temporary fixation substrate 1.

### (Confirmation of Effect of Polishing of Lateral End)

For each of five types of temporary fixation substrates 1 having different values of the arithmetic average roughness Ra of the lateral end 1e while having the chamfered region 2 formed similarly to that under Condition 3 (Conditions 3-1 to 3-5), 200 temporary fixation substrates 1 were prepared. The arithmetic average roughness Ra was measured under a laser microscope. For each of three types of temporary fixation substrates 1 having different values of the arithmetic average roughness Ra of the lateral end 1e while having the chamfered region 2 formed similarly to that under Condition 4 (Conditions 4-1 to 4-3), 200 temporary fixation substrates 1 were prepared. Furthermore, for each of two types of temporary fixation substrates 1 having different values of the arithmetic average roughness Ra of the lateral end 1e without having the chamfered region 2 as that under Condition 6 (Conditions 6-1 to 6-2), 200 temporary fixation substrates 1 were prepared.

The lateral end 1e of each of the temporary fixation substrates 1 was observed under a stereo microscope to determine whether chipping occurred. It was determined that chipping occurred, in the case that a crack having a size of 5 mm or more in a circumferential direction of the temporary fixation substrate 1 and a size of 1 mm or more in a radial direction of the temporary fixation substrate 1 was identified.

Table 2 shows a list of a value of the arithmetic average roughness Ra of the chamfered region 2, a value of the arithmetic average roughness Ra of the lateral end 1e, and an evaluation result of the chipping failure rate for each of Examples.

TABLE 2

| | CHAMFERED | LATERAL | CHIPPING |
|---|---|---|---|
| ROUGHNESS | REGION | END | FAILURE |
| Ra | (μm) | (μm) | RATE |
| CONDITION 3-1 | 9.5 | 1.1 | ⊚ |
| CONDITION 3-2 | 9.5 | 5.0 | Δ |
| CONDITION 3-3 | 9.5 | 0.2 | ⊚ |
| CONDITION 3-4 | 9.5 | 3.5 | Δ |
| CONDITION 3-5 | 9.5 | 9.0 | X |
| CONDITION 4-1 | 1.5 | 5.0 | Δ |
| CONDITION 4-2 | 1.5 | 1.5 | ⊚ |
| CONDITION 4-3 | 1.5 | 0.4 | ⊚ |
| CONDITION 6-1 | W/O CHAMFERED | 8.0 | X |
| | REGION | | |
| CONDITION 6-2 | W/O CHAMFERED | 1.5 | ◯ |
| | REGION | | |

As for evaluation of the chipping failure rate, it was determined that chipping was extremely successfully suppressed when the chipping failure rate had a value of 0.5% or less. Specifically, Conditions 3-1, 3-3, 4-2, and 4-3 corresponded to these conditions. In Table 2, a “CHIPPING FAILURE RATE” column for each of these conditions is marked with a double circle.

It was determined that chipping was generally successfully suppressed when the chipping failure rate had a value of more than 0.5% and 1.0% or less. Specifically, Condition 6-2 corresponded to this condition. In Table 2, the “CHIPPING FAILURE RATE” column for this condition is marked with a circle.

Furthermore, it was determined that chipping was suppressed to some extent when the chipping failure rate had a value of more than 1.0% and less than 3.0%. Specifically, Conditions 3-2, 3-4, and 4-1 corresponded to these conditions. In Table 2, the “CHIPPING FAILURE RATE” column for each of these conditions is marked with a triangle.

On the other hand, it was determined that chipping was insufficiently suppressed when the chipping failure rate had a value of more than 3%. Specifically, Conditions 3-5 and 6-1 corresponded to these conditions. In Table 2, the “CHIPPING FAILURE RATE” column for each of these conditions is marked with a cross. For example, the chipping failure rate under Condition 6-1 was 4.0%.

The above-mentioned results show that the lateral end 1e having an arithmetic average roughness Ra of 5 μm or less has some effect of suppressing chipping of the lateral end 1e, specifically, suppresses a rate of chipping to less than 3%. The above-mentioned results also show that the rate of chipping is suppressed to 1% or less when the lateral end 1e has an arithmetic average roughness Ra of 2 μm or less, and, in addition, the rate of chipping is suppressed to 0.5% or less when the temporary fixation substrate 1 further has the chamfered region 2.

While the invention has been shown and described in detail, the foregoing description is in all aspects illustrative and not restrictive. It is therefore understood that numerous modifications and variations can be devised without departing from the scope of the invention.

What is claimed is:

1. A temporary fixation substrate comprising:
one main surface to which a predetermined fixed object is temporarily fixed;
the other main surface; and
a chamfered region at an end over an entire circumference of each of the one main surface and the other main surface, wherein
an arithmetic average roughness of the chamfered region at least on a side of the one main surface is 0.1 μm to 10 μm and is greater than an arithmetic average roughness of the one main surface.

2. The temporary fixation substrate according to claim 1, wherein
the chamfered region comprises:
a first chamfer; and
a second chamfer, and
the first chamfer and the second chamfer have different angles of inclination relative to the one main surface.

3. The temporary fixation substrate according to claim 1, wherein
the one main surface and the other main surface each have an arithmetic average roughness of 100 nm or less.

4. The temporary fixation substrate according to claim 1, wherein
a lateral end of the temporary fixation substrate has a smaller arithmetic average roughness than the chamfered region.

5. The temporary fixation substrate according to claim 4, wherein
the arithmetic average roughness of the lateral end of the temporary fixation substrate is greater than the arithmetic average roughness of the one main surface and is 5 μm or less.

6. The temporary fixation substrate according to claim 5, wherein
the arithmetic average roughness of the lateral end of the temporary fixation substrate is 2 μm or less.

7. The temporary fixation substrate according to claim 1, wherein
the predetermined fixed object is a plurality of electronic components or a semiconductor substrate.

8. A method of manufacturing a temporary fixation substrate having one main surface to which a predetermined fixed object is temporarily fixed, the method comprising:
a) preparing a disc-shaped molded body mainly including a translucent ceramic;
b) firing the molded body to obtain a sintered body;
c) forming a chamfered region at an end over an entire circumference of each of one main surface and the other main surface of the sintered body; and
d) polishing the sintered body having the chamfered region to obtain the temporary fixation substrate, wherein
in d), an arithmetic average roughness of the chamfered region at least on a side of one main surface of the temporary fixation substrate is caused to be 0.1 μm to 10 m and have a greater value than an arithmetic average roughness of the one main surface of the temporary fixation substrate.

9. The method according to claim 8, wherein
in c), the chamfered region is formed in two steps including a first chamfer and a second chamfer having different angles of inclination relative to the one main surface of the temporary fixation substrate.

10. The method according to claim 8, wherein
in d), the one main surface and the other main surface of the temporary fixation substrate are each caused to have an arithmetic average roughness of 100 nm or less.

11. The method according to claim 8, wherein
in d), a lateral end of the temporary fixation substrate is caused to have a smaller arithmetic average roughness than the chamfered region.

12. The method according to claim 11, wherein
the arithmetic average roughness of the lateral end of the temporary fixation substrate is caused to be greater than the arithmetic average roughness of the one main surface of the temporary fixation substrate and have a value of 5 μm or less.

13. The method according to claim 8, wherein
the predetermined fixed object is a plurality of electronic components or a semiconductor substrate.

14. A method of temporarily fixing a predetermined fixed object to a temporary fixation substrate, the method comprising:
a) preparing a temporary fixation substrate having a chamfered region at an end over an entire circumference of one main surface;
b) forming an adhesive layer on the temporary fixation substrate;
c) disposing the predetermined fixed object on the adhesive layer; and
d) curing the adhesive layer into an adhering layer so that the predetermined fixed object adheres to the temporary fixation substrate, wherein
an arithmetic average roughness of the chamfered region is 0.1 μm to 10 μm and is greater than an arithmetic average roughness of the one main surface.

15. The method according to claim 14, wherein
the chamfered region includes a first chamfer and a second chamfer having different angles of inclination relative to the one main surface.

16. The method according to claim 14, wherein
the predetermined fixed object is a plurality of electronic components, and
the method further comprises
e) forming a resin mold on the adhering layer and the plurality of electronic components adhering to the temporary fixation substrate via the adhering layer.

17. The method according to claim 14, wherein
the predetermined fixed object is a semiconductor substrate.

18. The temporary fixation substrate according to claim 2, wherein
a lateral end of the temporary fixation substrate has a smaller arithmetic average roughness than the chamfered region.

19. The temporary fixation substrate according to claim 18, wherein
the arithmetic average roughness of the lateral end of the temporary fixation substrate is greater than the arithmetic average roughness of the one main surface and is 5 m or less.

20. The method according to claim 9, wherein
in d), a lateral end of the temporary fixation substrate is caused to have a smaller arithmetic average roughness than the chamfered region.
